(19) United States
(12) Patent Application Publication
(10) Pub. No.: US 2025/0280522 A1
(43) Pub. Date: Sep. 4, 2025

(54) DISPLAY DEVICE

(71) Applicant: FUJI CORPORATION, Chiryu (JP)

(72) Inventors: Mitsuru SANJI, Toyota-shi (JP); Kenji HARA, Kariya-shi (JP)

(73) Assignee: FUJI CORPORATION, Chiryu (JP)

(21) Appl. No.: 18/703,013

(22) PCT Filed: Nov. 5, 2021
(86) PCT No.: PCT/JP2021/040835

§ 371 Date: Apr. 19, 2024

(51) Int. Cl. H05K 13/08; G06F 3/0482

(52) U.S. Cl. CPC H05K 13/0888; G06F 3/0482

(57) ABSTRACT

A display device includes a display section and a control section, and displays an operation to be executed by a user in a component mounting line on a process-by-process basis on the display section. The control section is configured to, when a first image illustrating a content of a first process to be currently executed by the user is being displayed on the display section and when there exists a second process to be executed by the user after the first process, display a second image for guiding the second process on the display section along with the first image.

### TECHNICAL FIELD

The technique disclosed in the present description relates to a display device that displays operation contents to be executed by a user in a component mounting line.

### BACKGROUND ART

JP-A-2016-225387 discloses a system for supporting component replenishment of a component feeder of a component mounter in a component mounting line. In this system, the component shortage time of each component feeder is predicted, and the shortest time among the times until the component shortage time of each component feeder reaches a predetermined warning time is displayed on a display section.

### BRIEF SUMMARY

### Technical Problem

In the technique of JP-A-2016-225387, a list of component feeders whose component shortage time arrives within the warning time is displayed, but is not taken into consideration in the operation currently executed by a user. The present description proposes a technique capable of more clearly knowing contents of processes to be executed by a user.

### Solution to Problem

A display device disclosed in the present description includes a display section and a control section, and displays an operation to be executed by a user in a component mounting line on a process-by-process basis on the display section. The control section is configured to, when a first image illustrating a content of a first process to be currently executed by the user is being displayed on the display section and when there exists a second process to be executed by the user after the first process, display a second image for guiding the second process on the display section along with the first image.

In the above display device, the first image illustrating the content of the first process to be currently executed by the user (that is, a process currently being executed) along with the second image for guiding the second process to be executed by the user after the first process are displayed on the display section. Therefore, the user can perform the operation while checking the content of the process currently being executed, and can easily know what process the user needs to execute next.

### BRIEF DESCRIPTION OF DRAWINGS

FIG. 1 is a schematic diagram illustrating a configuration of a component mounting system.

FIG. 2 is a schematic diagram illustrating a configuration of a component mounter.

FIG. 3 is a cross-sectional view taken along line III-III of FIG. 2.

FIG. 4 is a block diagram illustrating configurations of the component mounter and a management device.

FIG. 5 is a diagram illustrating an example of a display format of contents to be executed by a user.

FIG. 6 is a diagram illustrating another example of the display format of the contents to be executed by the user.

FIG. 7 is a diagram illustrating still another example of the display format of the contents to be executed by the user.

FIG. 8 is a diagram illustrating yet still another example of the display format of the contents to be executed by the user.

FIG. 9 is a diagram illustrating an example of a display format of a detailed image.

FIG. 10 is a diagram illustrating an example of a display format of an image illustrating contents of processes for resolving an error.

### DESCRIPTION OF EMBODIMENTS

Main features of an example, which will be described below, will be listed. Technical elements, which will be described below, are each independent technical elements and are designed to exhibit technical usefulness alone or by being combined together in various ways, and the combinations are not limited to those described in claims.

In one embodiment of the present technique, the second image may illustrate only a part of a content of the second process.

In such a configuration, only the part of the content of the second process is displayed on the display section. Therefore, while the user can know the existence of the second process to be executed after the first process, the user can easily concentrate on the first process to be currently executed without being distracted by the existence of the second process.

In one embodiment of the present technique, the part of the content of the second process may be one or multiple elements selected from a process name, an operation name, an operation location, an operation start time, and an operation content of the second process.

In such a configuration, the user can more specifically know the content of the second process.

In one embodiment of the present technique, the control section may be configured to, as an operation start time of the second process approaches, change and display a content of the second image in a format in which the user more easily recognizes the content of the second image.

In such a configuration, the user can gradually and easily recognize a guidance of the second process included in the second image. In other words, as the operation start time of the second process approaches, the user can know many contents related to the second process, and can smoothly transition to the second process.

In one embodiment of the present technique, the control section may be configured to, as the operation start time of the second process approaches, increase the content of the second process to be displayed as the second image.

In such a configuration, since the amount of information (for example, display items) related to the second process increases as the operation start time of the second process approaches, the user can smoothly transition to the second process.

In one embodiment of the present technique, the control section may be configured to, when a third process which is different from the second process and which is to be executed by the user exists after the first process and either simultaneously with or after the second process, display a third image for guiding the third process on the display section along with the first image and the second image.

In such a configuration, when there exists the third process to be executed simultaneously with the second process or after the second process, the user can perform the operation while checking the content of the process currently being executed and also know the existence of the third process.

In one embodiment of the present technique, the control section may be configured to, when the operation start time of the second process and an operation start time of the third process are the same, assign priority, which is to be executed preferentially, to the second process and the third process, and display an image for guiding a process assigned a first priority in a format in which the user more easily recognizes the image for guiding the process assigned the first priority than an image for guiding a process assigned a second priority.

In such a configuration, the process to be executed first among the second process and the third process is displayed in a format that is easily recognizable, so that the user can easily know what is to be executed after the process currently being executed.

In one embodiment of the present technique, the second image may include a first selection image for the user to select to execute the second process before the first process, and the control section may be configured to, when the first selection image is selected by the user, display the second image in a format in which the user more easily recognizes the second image than the first image.

In such a configuration, for example, when the user determines that the second process needs to be executed before the first process, the user can know the content of the second process in more detail by selecting the first selection image.

In one embodiment of the present technique, the control section may be configured to, when the first image and the second image are being displayed on the display section, further display a second selection image for the user to select to display a detailed image illustrating a list of operations to be executed by the user in the future on the display section, and when the second selection image is selected by the user, display the detailed image on the display section.

In such a configuration, what kind of operations the user is scheduled to perform in the future is displayed as a list. Therefore, the user can know the future operation contents at once.

In one embodiment of the present technique, the control section may be configured to, when an error occurs in the component mounting line while the first image is being displayed on the display section, display a fourth image illustrating a content of a process to be executed by the user to resolve the error on the display section in a format in which the user more easily recognizes the fourth image than the second image.

When an error occurs in the component mounting line, it is preferable to quickly resolve the error. In the above configuration, when an error occurs in any part of the component mounting line while executing the first process, the content of the process to be executed to resolve the error is displayed in a format in which the user more easily recognizes the content of the process to be executed to resolve the error than the content of the second process to be executed after the first process. Accordingly, the user can know that an error has occurred, and can quickly address the error.

### EXAMPLE

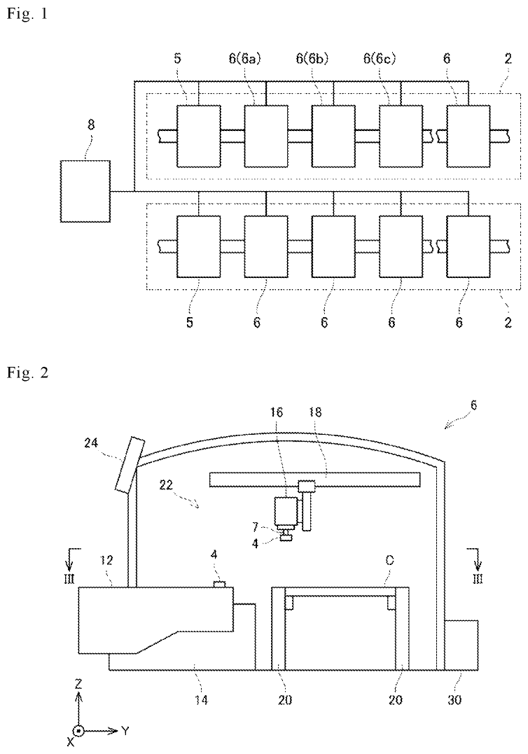

Hereinafter, component mounting system 1 of an example will be described. As illustrated in FIG. 1, component mounting system 1 includes two component mounting lines 2 and management device 8. Each component mounting line 2 has a function of manufacturing a mounting board by mounting electronic components 4 on board C, and mainly includes solder printer 5 and multiple component mounters 6. Solder printer 5 is a device that prints cream solder on board C. Component mounter 6 is a device that mounts electronic components 4 on board C on which the cream solder is printed. Although not illustrated in FIG. 1, component mounting line 2 is further provided with a print inspection machine which is disposed downstream of solder printer 5 and inspects the state of the cream solder printed on board C, a visual inspection machine which is disposed downstream of component mounter 6 and inspects the state of board C on which electronic components 4 is mounted, a reflow oven which is disposed downstream of the visual inspection machine and heats board C to reflow solder electronic components 4, and the like. Management device 8 controls operations of various devices incorporated in each component mounting line 2, and manages mounting of electronic components 4 on board C in each component mounting line 2.

Next, the configuration of component mounter 6 will be described. As illustrated in FIGS. 2 to 4, component mounter 6 includes component mounting section 22, interface device 24, and control device 30. Component mounting section 22 includes multiple component feeders 12, feeder holding section 14, mounting head 16, head moving device 18, and board conveyor 20.

Each component feeder 12 accommodates multiple electronic components 4. Component feeder 12 is detachably attached to feeder holding section 14 and supplies electronic components 4 to mounting head 16. A specific configuration of component feeder 12 is not particularly limited. Each component feeder 12, for example, may be any of a tape-type feeder for accommodating multiple electronic components 4 on a wound tape, a tray-type feeder for accommodating multiple electronic components 4 on a tray, or a bulk-type feeder for accommodating multiple electronic components 4 randomly in a container.

Feeder holding section 14 includes multiple slots, and component feeder 12 can be detachably installed in each slot. Feeder holding section 14 may be fixed to component mounter 6 or may be detachable from component mounter 6. Mounting head 16 detachably holds one or multiple nozzles 7, uses nozzle 7 to pick up electronic components 4 supplied by component feeder 12, and mounts electronic components 4 on board C. At this time, head moving device 18 moves mounting head 16 with respect to component feeder 12 and board C. Accordingly, electronic components 4 are picked up from specific component feeder 12 of multiple component feeders 12, and electronic components 4 are mounted on a position determined on board C in advance. Board conveyor 20 conveys in, supports, and conveys out board C.

Interface device 24 is a device that provides the user with various information on component mounter 6 and is a device that receives instructions and information from the user. In the present example, interface device 24 is a touch panel, but may include, for example, a display and a keyboard or a mouse.

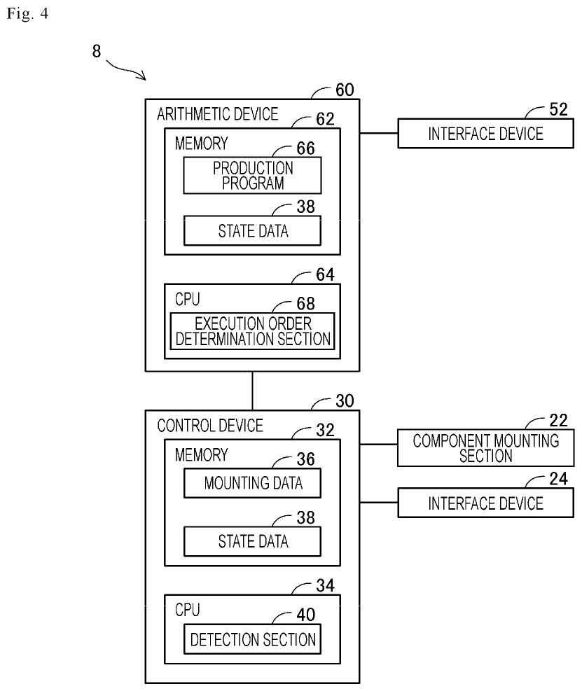

Control device 30 is communicably configured with management device 8. Control device 30 controls the operation of each element of component mounter 6 in response to instructions from management device 8. As illustrated in FIG. 4, control device 30 is configured with a computer including memory 32 and CPU 34. Control device 30 refers to mounting data 36 (received from management device 8) stored in memory 32 to control the operation of component mounting section 22 and the like, and to mount electronic components 4 on board C. In addition, CPU 34 includes detection section 40 that detects state data 38 indicating the state of the mounting process in the process of executing the mounting process on board C. In memory 32, state data 38 detected by detection section 40 is stored in real time. State data 38 includes, for example, mounting line data for identifying each component mounting line 2, mounter data for identifying each component mounter 6, slot data indicating a position of a slot in which each component feeder 12 is mounted, component type data indicating a component type accommodated in each component feeder 12, and component shortage time data indicating a time until each component feeder 12 runs out of components. Control device 30 transmits state data 38 to management device 8 at predetermined intervals.

Next, the configuration of management device 8 will be described. As illustrated in FIG. 4, management device 8 includes interface device 52 and arithmetic device 60.

Interface device 52 is a device that provides the user with various information on component mounting line 2 and is a device that receives instructions and information from the user. In particular, as will be described later, interface device 52 of the present example functions as a device that notifies the user of contents of operations to be executed by the user in the mounting process in component mounting line 2. In the present example, interface device 52 is a touch panel, but may include, for example, a display and a keyboard or a mouse.

Arithmetic device 60 is configured with a computer including memory 62 and CPU 64. Production program 66 is stored in memory 62. The operation of entire component mounting line 2 is described in production program 66, and arithmetic device 60 instructs the various devices incorporated in component mounting line 2 to perform the operation to be executed by each device according to production program 66. Memory 62 stores multiple state data 38 transmitted from each control device 30 of each component mounter 6. CPU 64 includes execution order determination section 68 that determines the order of operations to be executed by the user. Based on multiple state data 38 received from each component mounter 6, execution order determination section 68 determines the order of operations to be executed by the user in the production of board C in component mounting system 1.

Next, in the production of board C in component mounting system 1, the process in which arithmetic device 60 displays contents of operations to be executed by the user on interface device 52 will be described. When board C is produced in component mounting line 2, there exist multiple operations to be executed by the user for each component mounter 6. Examples of the contents of the operations include a component replenishment operation (that is, an exchange operation of component feeder 12) caused by a decrease in the number of components accommodated in component feeder 12 and an exchange operation of nozzle 7 caused by a change in the type of electronic components 4 to be mounted. In the present example, arithmetic device 60 displays these operations to be executed by the user on a process-by-process basis on interface device 52. In the present description, both terms are used so that “operation” has a broader concept than “process”. That is, one or multiple “processes” exist for one “operation”.

As processes in the exchange operation of component feeder 12, there are processes such as carrying component feeder 12 accommodating the electronic components of the designated type to component mounter 6 targeted for exchange, replacing component feeder 12, and returning detached component feeder 12 to a predetermined position. As processes in the exchange operation of nozzle 7, there are processes such as carrying a nozzle holder in which nozzle 7 of the designated type is accommodated to component mounter 6 targeted for exchange, replacing the nozzle holder, and returning the detached nozzle holder to a predetermined position.

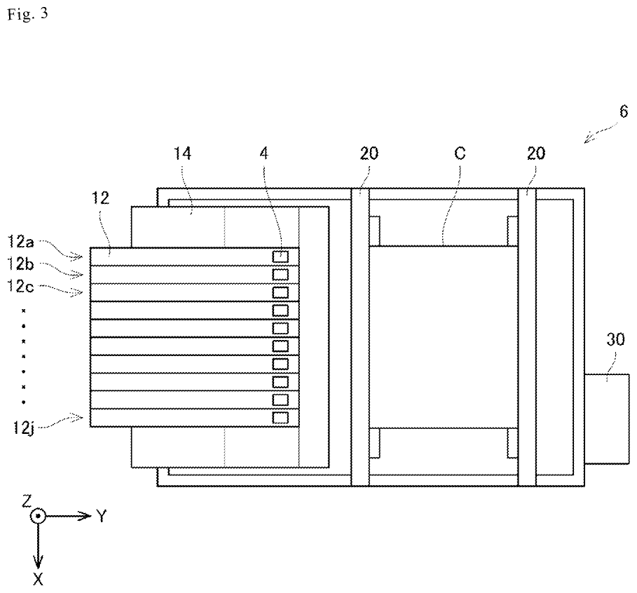

First, arithmetic device 60 determines the order of operations to be executed by the user based on state data 38 received from each component mounter 6 and production program 66. Specifically, arithmetic device 60 calculates a time at which each component feeder 12 is to be exchanged based on the component shortage time data, a time at which nozzle 7 is to be exchanged based on production program 66, and the like, and rearranges the target operation in ascending order of arrival time. Hereinafter, a situation in which the component shortage time of electronic component 4a in component feeder 12 in slot 12a of component mounter 6a of component mounting line 2a (refer to FIGS. 1 and 3) arrives earliest and the exchange operation of component feeder 12 is to be currently executed will be described. In addition, it is assumed a situation that there exists an operation of exchanging the nozzle provided in component mounter 6c with nozzle 7a as an operation to be executed after the exchange operation of component feeder 12 in slot 12a.

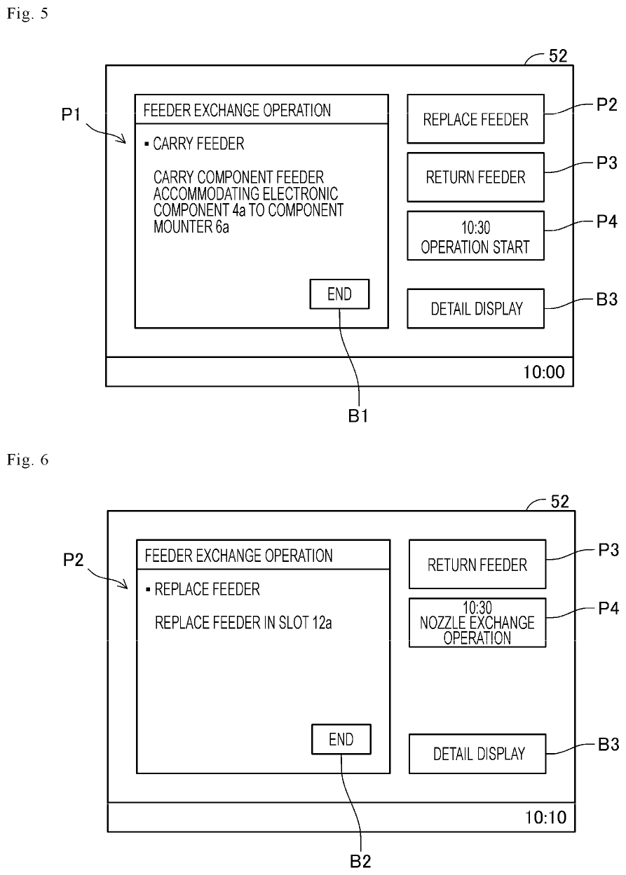

Based on state data 38, arithmetic device 60 displays image P1 illustrating the content of a process to be currently executed by the user on interface device 52 as illustrated in FIG. 5. With reference to state data 38, arithmetic device 60 displays a character string “Feeder Exchange Operation” indicating the operation name, a character string “Carry Feeder” indicating the process name, and a character string “Carry component feeder accommodating electronic component 4a to component mounter 6a” indicating the operation location and the operation content as image P1.

In addition, since there exists a process of replacing component feeder 12 in slot 12a after the process illustrated in image P1, arithmetic device 60 displays image P2 that guides the process on interface device 52 along with image P1. Arithmetic device 60 displays a character string “Replace Feeder” indicating only the process name as image P2. The process illustrated in image P2 is a process to be executed after the process illustrated in image P1. Image P2 is displayed in a smaller size than image P1. In the present example, image P2 is displayed on the right side of the display area of interface device 52.

In addition, since there exists a process of returning detached component feeder 12 after the process illustrated in image P2, arithmetic device 60 displays image P3 that guides the process on interface device 52 along with images P1 and P2. Arithmetic device 60 displays a character string “Return Feeder” indicating only the process name as image P3. Image P3 is displayed below image P2 in substantially the same size as image P2.

After the process illustrated in image P3, as described above, there exists the exchange operation of nozzle 7 of component mounter 6c. Therefore, arithmetic device 60 displays image P4 that guides the process on interface device 52 along with images P1 to P3. Arithmetic device 60 displays a character string “10:30 Operation Start” indicating only the operation start time as image P4. Image P4 is displayed below image P3 in substantially the same size as image P3.

Image P1 includes end button B1 for the user to input that the process to be currently executed has ended. When component feeder 12 is carried to component mounter 6a according to image P1 displayed on interface device 52, the user touches end button B1 included in image P1. Accordingly, arithmetic device 60 can detect that the process to be currently executed has ended.

When detecting the input to end button B1, arithmetic device 60 ends the display of image P1 and enlarges and displays image P2 at the center of the display area of interface device 52 as illustrated in FIG. 6. Arithmetic device 60 displays, as image P2, a character string “Feeder Exchange Operation” indicating the operation name, a character string “Replace Feeder” indicating the process name, and a character string “Replace feeder in slot” indicating the operation location and the operation content, in place of the format illustrated in FIG. 5. That is, arithmetic device 60 displays, as image P2, an image specifically indicating the content of the process of “Replace Feeder” in place of the image (FIG. 5) that guides the process of “Replace Feeder”. Arithmetic device 60 moves image P3 and image P4 upward and displays image P3 and image P4. Here, arithmetic device 60 displays, as image P4, a character string “Nozzle Exchange Operation” indicating the operation name in addition to the operation start time illustrated in FIG. 5. That is, arithmetic device 60 increases the display content of the process illustrated in image P4 compared to the format illustrated in FIG. 5.

Similarly to image P1 illustrated in FIG. 5, image P2 illustrated in FIG. 6 includes end button B2 for inputting that the process to be currently executed has ended. When component feeder 12 is replaced, the user touches end button B2. Accordingly, arithmetic device 60 can detect that the process to be currently executed has ended.

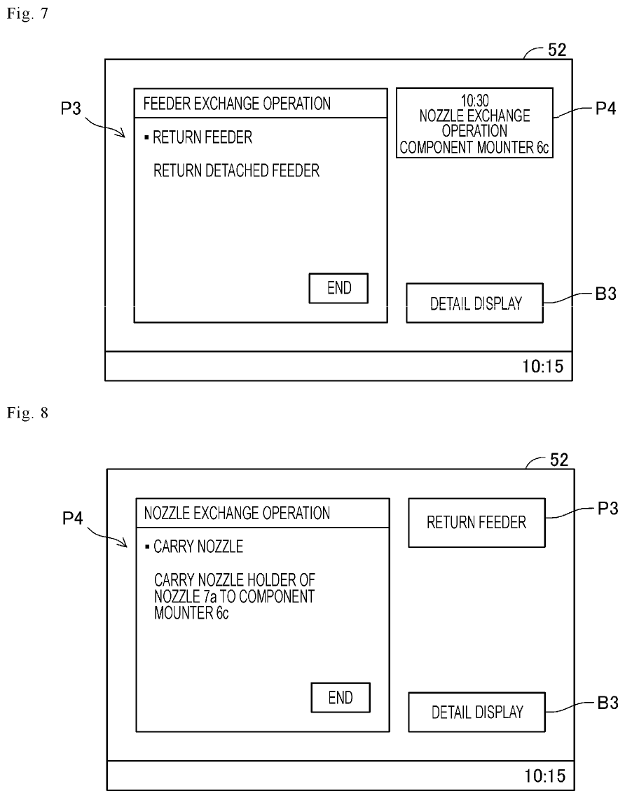

When detecting the input to end button B2, arithmetic device 60 ends the display of image P2 and enlarges and displays image P3 at the center of the display area of interface device 52 as illustrated in FIG. 7. Arithmetic device 60 displays, as image P3, a character string “Feeder Exchange Operation” indicating the operation name, a character string “Return Feeder” indicating the process name, and a character string “Return detached feeder” indicating the operation location and the operation content, in place of the format illustrated in FIG. 6. Arithmetic device 60 moves image P4 upward and displays image P4. Here, arithmetic device 60 displays, as image P4, a character string “Component Mounter 6c” indicating the operation location in addition to the operation start time and the operation name illustrated in FIG. 6. That is, arithmetic device 60 increases the display content of the process illustrated in image P4 compared to the format illustrated in FIG. 6.

As described above, arithmetic device 60 displays the content of the operation to be executed by the user in order on a process-by-process basis. Specifically, arithmetic device 60 displays an image (for example, image P2 in FIG. 5) that guides the process to be executed after the process along with the content of the process to be currently executed by the user (for example, image P1 in FIG. 5). Therefore, the user can perform the operation while checking the content of the process currently being executed, and can easily know what process the user needs to execute next.

Further, in the above example, for example, in the format illustrated in FIG. 5, images P2 to P4 that guide the process subsequent to the process illustrated in image P1 are displayed, and only a part of the content of the process is displayed. Therefore, while the user can recognize that there is a process subsequent to the process currently being executed, the user can easily concentrate on the process illustrated in image P1 without being distracted by the existence of the subsequent process.

In the above example, as illustrated in FIGS. 5 to 7, the display content of image P4 increases as the operation start time of the process illustrated in image P4 approaches. Therefore, a large amount of content can be gradually obtained in relation to the process illustrated in image P4, and the user can smoothly transition to the process.

In the present example, component mounting system 1 includes multiple component mounting lines 2. Therefore, in each component mounting line 2, there may exist two processes that start at the same time. In such a case, arithmetic device 60 assigns priority, which is to be preferentially executed, to the two processes. Then, arithmetic device 60 displays the process with a higher priority in a format in which the user more easily recognizes the process with the higher priority than the process with a lower priority (in the format illustrated in FIG. 5 and the like, upward). Here, for example, when each of two component mounting lines 2 includes a pre-process and a post-process for production of board C, arithmetic device 60 may assign a higher priority to a process in component mounting line 2 that executes the pre-process. With this configuration, the user can easily know the process to be executed first.

Further, for example, in the situation illustrated in FIG. 7, there may be a case where the user prefers to execute the process illustrated by image P4 (that is, nozzle exchange operation) before the process of returning the feeder due to a balance of operations with other users. In such a case, the user touches image P4. When an input operation to image P4 is detected, arithmetic device 60 switches the positions of image P4 and image P3 and displays the positions as illustrated in FIG. 8. Here, in place of the format illustrated in FIG. 7, arithmetic device 60 displays, as image P4, a character string “Nozzle Exchange Operation” indicating the operation name, a character string “Carry Nozzle” indicating the process name, and a character string “Carry nozzle holder of nozzle 7a to component mounter 6c” indicating the operation location and the operation content. With this configuration, convenience is improved when the user prefers to change the order of process to be executed for some reason.

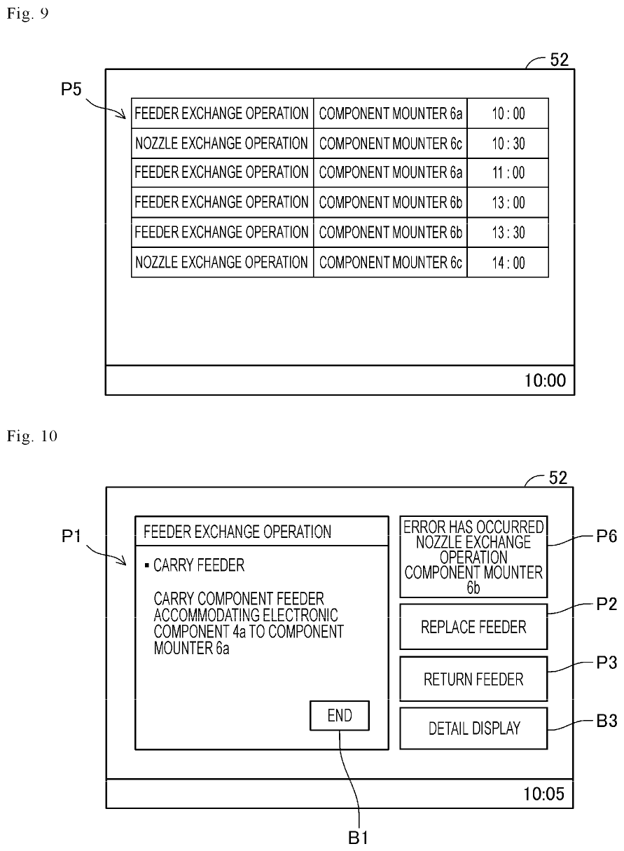

While the user is executing the operation, arithmetic device 60 displays detail display button B3 on interface device 52 as illustrated in FIG. 5 and the like. Detail display button B3 is a button for displaying detailed image P5 illustrating a list of operations to be executed by the user in the future. When detecting the input to detail display button B3, arithmetic device 60 displays detailed image P5 at the center of the display area of interface device 52 as illustrated in FIG. 9. In the example illustrated in FIG. 9, detailed image P5 includes an operation name, an operation location, and an operation start time. In such a configuration, since what kind of operations the user is scheduled to perform in the future is displayed as a list, the user can know the contents of the future operations at once. The display content of detailed image P5 is not limited to the example illustrated in FIG. 9. For example, a process name may be further displayed.

When board C is produced in component mounting system 1, an error may occur in any of component mounters 6. For example, when an error exceeding a predetermined threshold value (for example, a mispicking of electronic components 4 by nozzle 7) occurs in component mounter 6b under the situation illustrated in FIG. 5, arithmetic device 60 displays image P6 illustrating the content of the process to be executed to resolve the error preferentially over images P2 to P4 as illustrated in FIG. 10. In the present example, image P6 is displayed above image P2 and image P3, and the display of image P4 is stopped. Image P6 includes a character string “Error Has Occurred” indicating that an error has occurred, a character string “Nozzle Exchange Operation” indicating a process to be executed to resolve the error, and an operation location “Component Mounter 6b”. In such a configuration, the user can easily know that an error has occurred, and can quickly address the error.

### Correspondence Relationship

Interface device 52 and arithmetic device 60 are examples of a “display section” and a “control section”, respectively. Management device 8 is an example of a “display device”. The feeder carry, the feeder replacement, and the feeder return illustrated in FIG. 5 are examples of a “first process”, a “second process”, and a “third process”, respectively. Image P1, image P2, and image P3 illustrated in FIG. 5 are examples of a “first image”, a “second image”, and a “third image”, respectively. Image P4 illustrated in FIG. 7 is an example of a “first selection image”. Detail display button B3 is an example of a “second selection image”. Image P6 in FIG. 10 is an example of a “fourth image”.

Although the specific example of the technique disclosed in the present description is described in detail, the specific example is merely an example, and does not limit the claims. The technique described in the scope of claims includes various modifications and changes of the specific examples described above. Hereinafter, modified examples of the above-described embodiment will be listed.

In the above-described example, an example in which the content of the operation for component mounter 6 in component mounting line 2 is displayed has been described. However, for example, the operation content for solder printer 5 incorporated in component mounting line 2 may be further displayed. Specifically, for example, processes such as a replenishment operation of a cream solder or an exchange operation of a mask may be further displayed.

In FIGS. 5 to 7, arithmetic device 60 gradually increases the content of the nozzle exchange operation as the start time of the nozzle exchange operation approaches, displaying the content as image P4. Similarly, as the start times of the processes illustrated in image P2 and image P3 approach, arithmetic device 60 may gradually increase and display the contents of these processes as images P2 and P3. Further, in place of the format gradually increasing the content of the nozzle exchange operation as the operation start time of the nozzle exchange operation approaches, for example, arithmetic device 60 may display image P4 such that the luminance or the brightness of image P4 gradually increases.

In addition, in the example described above, arithmetic device 60 displays the content of the operation to be executed by the user on interface device 52 of management device 8, but the content may be displayed on interface device 24 of each component mounter 6 or on interface devices (not illustrated) of other working machines incorporated in component mounting line 2, or may be displayed on a device separate from these devices.

Technical elements described in the present description or the drawings exhibit technical usefulness alone or in various combinations, and are not limited to combinations described in claims as filed. In addition, the technique exemplified in the present description or the drawings simultaneously achieves multiple purposes, and achieving one of the purposes itself has technical usefulness.

1. A display device comprising:
a display section; and
a control section,
the display device being for displaying an operation to be executed by a user in a component mounting line on a process-by-process basis on the display section, wherein
the control section is configured to, when a first image illustrating a content of a first process to be currently executed by the user is being displayed on the display section and when there exists a second process to be executed by the user after the first process, display a second image for guiding the second process on the display section along with the first image.

2. The display device according to claim 1, wherein the second image illustrates only a part of a content of the second process.

3. The display device according to claim 2, wherein the part of the content of the second process is one or multiple elements selected from a process name, an operation name, an operation location, an operation start time, and an operation content of the second process.

4. The display device according to claim 2, wherein the control section is configured to, as the operation start time of the second process approaches, change and display a content of the second image in a format in which the user more easily recognizes the content of the second image.

5. The display device according to claim 4, wherein the control section is configured to, as the operation start time of the second process approaches, increase the content of the second process to be displayed as the second image.

6. The display device according to claim 1, wherein the control section is configured to, when a third process which is different from the second process and which is to be executed by the user exists after the first process and either simultaneously with or after the second process, display a third image for guiding the third process on the display section along with the first image and the second image

7. The display device according to claim 6, wherein the control section is configured to, when the operation start time of the second process and an operation start time of the third process are the same, assign priority, which is to be executed preferentially, to the second process and the third process, and display an image for guiding a process assigned a first priority in a format in which the user more easily recognizes the image for guiding the process assigned the first priority than an image for guiding a process assigned a second priority.

8. The display device according to claim 1,
wherein the second image includes a first selection image for the user to select to execute the second process before the first process, and
the control section is configured to, when the first selection image is selected by the user, display the second image in a format in which the user more easily recognizes the second image than the first image.

9. The display device according to claim 1,
wherein the control section is configured to,
when the first image and the second image are being displayed on the display section, further display a second selection image for the user to select to display a detailed image illustrating a list of operations to be executed by the user in the future on the display section, and
when the second selection image is selected by the user, display the detailed image on the display section.

10. The display device according to claim 1, wherein the control section is configured to, when an error occurs in the component mounting line while the first image is being displayed on the display section, display a fourth image illustrating a content of a process to be executed by the user to resolve the error on the display section in a format in which the user more easily recognizes the fourth image than the second image.
